(19) United States
(12) Patent Application Publication
(10) Pub. No.: US 2018/0149315 A1
(43) Pub. Date: May 31, 2018

(54) GAS CABINETS

(71) Applicant: ENTEGRIS, INC., Billerica, MA (US)

(72) Inventors: Joseph R. DESPRES, Middletown, CT (US); Barry Lewis CHAMBERS, Midlothian, VA (US); Joseph D. Sweeney, New Milford, CT (US); Richard S. RAY, Phoenix, AZ (US); Steven E. BISHOP, Corrales, NM (US)

(21) Appl. No.: 15/574,617

(22) PCT Filed: May 16, 2016
(86) PCT No.: PCT/US2016/032741

§ 371 Date: Nov. 16, 2017

Related U.S. Application Data
(60) Provisional application No. 62/162,777, filed on May 17, 2015.

(51) Int. Cl. F17C 7/00; H01L 21/67; F17C 11/00; F17C 13/00

(52) U.S. Cl. CPC F17C 7/00; H01L 21/67017; F17C 11/00; F17C 13/00; F17C 2221/03; F17C 2223/0123; F17C 2270/0518; F17C 2227/0107; F17C 2227/042; F17C 2250/032; F17C 2250/043; F17C 2250/0447; F17C 2250/0626; F17C 2225/0123

(57) ABSTRACT

Gas supply systems and methods are described for delivery of gas to gas-utilizing process tools, e.g., gas-utilizing tools for manufacturing of semiconductor products, flat-panel displays, solar panels, etc. The gas supply systems may comprise gas cabinets that are arranged with adsorbent-based and/or interiorly pressure-regulated gas supply vessels therein, and a gas mixing manifold is described, which may be disposed in the gas cabinet or operated in a standalone fashion. In one aspect, gas supply systems are described in which vessels susceptible to cooling involving diminution of gas supply pressure are processed after pressure-controlled termination of dispensing operation, for dispensing operation achieving utilization of gas remaining in the vessel after such termination.

### CROSS-REFERENCE TO RELATED APPLICATION

The benefit of U.S. Provisional Patent Application No. 62/162,777 filed May 17, 2015 in the names of Joseph R. Despres, Barry Lewis Chambers, Joseph D. Sweeney, Richard S. Ray, and Steven E. Bishop for “GAS CABINETS” is claimed under the provisions of 35 USC 119. The disclosure of U.S. Provisional Patent Application No. 62/162,777 is hereby incorporated herein by reference, in its entirety, for all purposes.

### FIELD

The present disclosure relates to gas mixing systems and methods, and to gas cabinets, having utility for supplying gas for gas-utilizing applications such as manufacturing of semiconductor products, flat panel displays, and photovoltaic panels.

### DESCRIPTION OF THE RELATED ART

In the use of gas supply vessels in a number of industrial applications, it is common practice to deploy the gas supply vessels in gas cabinets, as enclosures in which the vessels are coupled to flow circuitry for delivery of gas to downstream gas-utilizing tools. The gas cabinets in such respect are containment structures in which, in addition to the flow circuitry for conducting gas dispensed from gas supply vessels in the gas cabinet to the downstream tool(s), monitoring and control instrumentation may be provided to ensure that gas is supplied from the gas cabinet at desired temperature, pressure, flow rate, and composition. The gas cabinet may also be configured with inlet and exhaust assemblies for flowing ventilation gas through the interior volume of the gas cabinet, so that any gas leakage from gas supply vessels in the gas cabinet, or from flow circuitry and couplings may be swept out of the gas cabinet and passed to a treatment facility or other disposition.

Due to the widespread use of gas cabinets in in supplying gas for industrial processes, the art continues to seek improvements in gas cabinet design, functionality, operation and use.

### SUMMARY

The present disclosure relates to gas supply systems and methods, and gas cabinets configured to contain gas supply vessels, for delivery of gas to gas-utilizing tools.

In one aspect, the disclosure relates to a gas supply system, comprising: at least one gas supply vessel susceptible to cooling in dispensing operation involving diminution of pressure of gas dispensed from the vessel; a monitoring system configured to detect diminution of pressure to pressure that is indicative of exhaustion of the vessel, and to terminate dispensing operation of the vessel; and a warming system configured to warm the vessel upon termination of dispensing operation thereof so that the vessel is warmed to an extent so that pressure of remaining gas in the vessel is increased above the pressure indicative of exhaustion of the vessel, to thereby enable renewed dispensing operation of the vessel.

In another aspect, the disclosure relates to a gas supply system for delivery of different co-flow gases containing a same dopant species, wherein the co-flow gases are delivered from respective vessels selected from among adsorbent-based gas supply vessels, internally pressure-regulated gas supply vessels, and combinations of the foregoing.

In a further aspect, the disclosure relates to a gas mixing system, comprising: a gas mixing manifold having multiple gas inputs have multiple mixed gas outputs; a monitoring and control system configured to operate the gas mixing manifold and to receive feedback therefrom via signal transmission lines; and at least one remote fiber-optic link interconnecting the monitoring and control system with at least one remote input/output interface unit.

A further aspect of the disclosure relates to a method of supplying gas from at least one gas supply vessel that is susceptible to cooling in dispensing operation involving diminution of pressure of gas dispensed from the vessel, said method comprising: monitoring pressure of gas dispensed from the vessel; upon detection of diminution of pressure to pressure that is indicative of exhaustion of the vessel, terminating dispensing operation of the vessel; and warming the vessel upon termination of dispensing operation thereof so that the vessel is warmed to an extent so that pressure of remaining gas in the vessel is increased above the pressure indicative of exhaustion of the vessel, to thereby enable renewed dispensing operation of the vessel.

A still further aspect of the disclosure relates to a method of supplying co-flow gases containing a same dopant species, comprising delivering the co-flow gases from respective vessels selected from among adsorbent-based gas supply vessels, internally pressure-regulated gas supply vessels, and combinations of the foregoing.

Yet another aspect of the disclosure relates to a method of supplying mixed gas, comprising mixing gases from different gas supply vessels in a gas mixing system of the present disclosure, and discharging mixed gas from the gas mixing manifold in one of the multiple mixed gas outputs thereof.

Other aspects, features and embodiments of the disclosure will be more fully apparent from the ensuing description and appended claims.

### BRIEF DESCRIPTION OF THE DRAWINGS

FIG. 1 is a perspective view, in partial section, of an adsorbent-based gas supply vessel that may be utilized in a gas cabinet in accordance with the present disclosure.

FIG. 2 is a perspective view, in partial section, of a pressure-regulated gas supply vessel that may be utilized in a gas cabinet in accordance with the present disclosure.

FIG. 3 is a schematic representation of a gas mixing system that may be utilized for supply of gas from gas supply vessels, e.g., in a gas cabinet of the present disclosure.

FIG. 4 is a front perspective view of a gas cabinet assembly incorporating adsorbent-based gas supply vessels according to one embodiment of the disclosure.

### DETAILED DESCRIPTION

The present disclosure relates to gas supply systems and methods, and gas cabinets, configured to supply gas to gas-utilizing tools, and having utility in manufacturing of semiconductor products, flat-panel displays, solar panels, etc.

In one aspect, the present disclosure relates to a gas supply system, comprising: at least one gas supply vessel susceptible to cooling in dispensing operation involving diminution of pressure of gas dispensed from the vessel; a monitoring system configured to detect diminution of pressure to pressure that is indicative of exhaustion of the vessel, and to terminate dispensing operation of the vessel; and a warming system configured to warm the vessel upon termination of dispensing operation thereof so that the vessel is warmed to an extent so that pressure of remaining gas in the vessel is increased above the pressure indicative of exhaustion of the vessel, to thereby enable renewed dispensing operation of the vessel.

In such system, the gas supply vessel may contain an adsorbent as a storage medium for gas to be supplied by the vessel in dispensing operation comprising gas desorption from the adsorbent. The adsorbent may for example comprise carbon adsorbent or other suitable adsorbent medium.

The warming system in such gas supply system may comprise a heater arranged to heat the gas supply vessel, e.g., a heating jacket or other thermal input device or assembly.

The above-described gas supply system may comprise a multiplicity of the gas supply vessels, operatively arranged so that when the monitoring system terminates dispensing operation of a first vessel, a second vessel initiates dispensing operation, to ensure continuity of gas supply. The gas supply system in such respect may be operatively arranged so that when the first vessel is warmed to enable its renewed dispensing operation, dispensing operation of the second vessel is terminated and renewed dispensing operation of the warmed first vessel is initiated.

In other embodiments of the gas supply system as above described, the gas supply vessel(s) may be disposed in the gas cabinet. Multiple gas supply vessels may be provided in the gas cabinet, operatively arranged with a mixing manifold for mixing gas dispensed from two or more of the multiple gas supply vessels.

The disclosure in another aspect relates to a gas supply system for delivery of different co-flow gases containing a same dopant species, wherein the co-flow gases are delivered from respective vessels selected from among adsorbent-based gas supply vessels, internally pressure-regulated gas supply vessels, and combinations of the foregoing. The different co-flow gases may for example comprise GeF₄ in a first gas supply vessel and GeH₄ in a second gas supply vessel.

Yet another aspect of the disclosure relates to a gas mixing system, comprising: a gas mixing manifold having multiple gas inputs have multiple mixed gas outputs; a monitoring and control system configured to operate the gas mixing manifold and to receive feedback therefrom via signal transmission lines; and at least one remote fiber-optic link interconnecting the monitoring and control system with at least one remote input/output interface unit.

In such gas mixing system, the remote input/output interface unit may be configured to transmit control signals either directly to the gas mixing manifold for operation thereof or to the monitoring and control system for operation of the gas mixing manifold. The system may comprise multiple remote input/output interface units, wherein the gas mixing system is configured with software interlocks to prevent incorrectly proportioned mixtures from being generated, and/or to avoid conflicts between process tool demands of one or more process tools coupled in gas mixture receiving relationship to the gas mixing manifold. The gas mixing manifold may be disposed in a gas cabinet. The gas mixing system may be configured for evacuation of the mixing manifold after each mixing operation therein. The mixing manifold may comprise onboard sensors configured to detect and/or verify gas purity and/or gas component proportions in a gas mixture produced by the manifold.

Another aspect of the disclosure relates to a method of supplying gas from at least one gas supply vessel that is susceptible to cooling in dispensing operation involving diminution of pressure of gas dispensed from the vessel, said method comprising: monitoring pressure of gas dispensed from the vessel; upon detection of diminution of pressure to pressure that is indicative of exhaustion of the vessel, terminating dispensing operation of the vessel; and warming the vessel upon termination of dispensing operation thereof so that the vessel is warmed to an extent so that pressure of remaining gas in the vessel is increased above the pressure indicative of exhaustion of the vessel, to thereby enable renewed dispensing operation of the vessel.

A further aspect of the disclosure relates to a method of supplying co-flow gases containing a same dopant species, comprising delivering the co-flow gases from respective vessels selected from among adsorbent-based gas supply vessels, internally pressure-regulated gas supply vessels, and combinations of the foregoing.

In another aspect, the disclosure relates to a method of supplying mixed gas, comprising mixing gases from different gas supply vessels in a gas mixing system of the present disclosure, and discharging mixed gas from the gas mixing manifold in one of the multiple mixed gas outputs thereof.

The foregoing aspects of the present disclosure are more fully described and elaborated hereafter.

In various gas supply operations, such as semiconductor manufacturing, high flow rates on the order of several liters per minute are required to be achieved from gas supply vessels such as adsorbent-based or pressure-regulated vessels.

A typical process may involve flow of 2 L per minute of gas for duration of two hours, followed by a non-flow period of 20 minutes as the gas-utilizing tool is changing out wafers. An additional two hour flow time would then follow this wait period. The process would continue to alternate between two hours of gas flow, followed by a 20 minute wait, throughout the day or other on-stream operating period. In this process, the minimum desired delivery pressure may be on the order of 300 torr. In this typical process, a gas cabinet may be employed in which two 50 L gas supply vessels are installed.

A problem encountered in the operation of this process is that as gas is flowed from the gas supply vessel during dispensing operation, the vessel will begin to cool, which causes the gas pressure in the vessel to decline. Once the gas supply vessel pressure reaches the 300 torr set point during such declining pressure dispensing operation, the gas cabinet monitoring and control system will interpret the declining pressure and set point arrival as indicative of exhaustion of the gas contents of the vessel, and it will switch off such “exhausted” vessel, e.g., by closure of the valve in the valve head of such vessel, and switch on a fresh gas supply vessel, e.g., by opening of the valve in the valve head of such fresh gas supply vessel, to ensure continuity of gas supply to the downstream gas-utilizing tool. In such manner, the original gas supply vessel will be placed out of service and scheduled for a change out involving removal of such vessel from the gas cabinet, and installation of a further fresh vessel containing the gas to be dispensed.

Thus, the cooling of the vessel incident to gas dispensing operation results in a premature indication of an empty or exhausted status of the gas supply vessel, at a point when it still has significant remaining gas for continued dispensing operation. This cooling-mediated indication of empty or exhausted status is particularly acute in the case of adsorbent-containing vessels, in which desorption of gas from the adsorbent storage medium contributes substantially to the cooling.

The present disclosure contemplates resolution of this problem by a modified gas monitoring and control system in or associated with the gas cabinet, which operates so that when the originally dispensing gas supply vessel is deemed to be “empty”, it is not thereupon scheduled for removal from the gas cabinet, but rather is maintained in an idle state, and warmed to temperature at which gas again can be dispensed from the vessel, so that the significant remaining inventory of gas in the vessel is then available for dispensing. Such warming may include warming of the vessel and its contents to above ambient (room) temperature and/or augmentative heating by actuating a heating jacket surrounding the vessel, or in other appropriate manner. The warming temperature may for example be warming to temperature in a range of from 35° C. to 50° C., in specific embodiments of the disclosure.

Such warming is carried out so that the prior cooling as a result of desorption of gas is overcome. Thus, the second gas supply vessel that has been switched to active dispensing operation may be utilized in the aforementioned process for a two-hour dispensing period, while the first gas supply vessel previously taken off-line as a result of monitored cooling is warmed to appropriate temperature to enable the first gas supply vessel to be utilized to supply gas for the next succeeding two hour dispensing period. Operation in this fashion enables a more thorough utilization of the gas inventory of each gas supply vessel, as well as decreasing the number of gas vessel change-outs that are required.

The disclosure in another aspect relates to co-flows of gases, in which different gases are concurrently flowed to a process tool, such as a vapor deposition chamber, epitaxial growth chamber, implantation chamber, or other gas-utilizing tool. Such gases in the case of ion implantation may comprise co-flow gases containing a same dopant species, e.g., GeF₄ and GeH₄, wherein the co-flow gases are delivered from respective vessels selected from among adsorbent-based gas storage and dispensing vessels, internally pressure-regulated vessels, i.e., vessels having interiorly disposed pressure-regulating devices, and combinations of such adsorbent-based and internally pressure-regulated vessels.

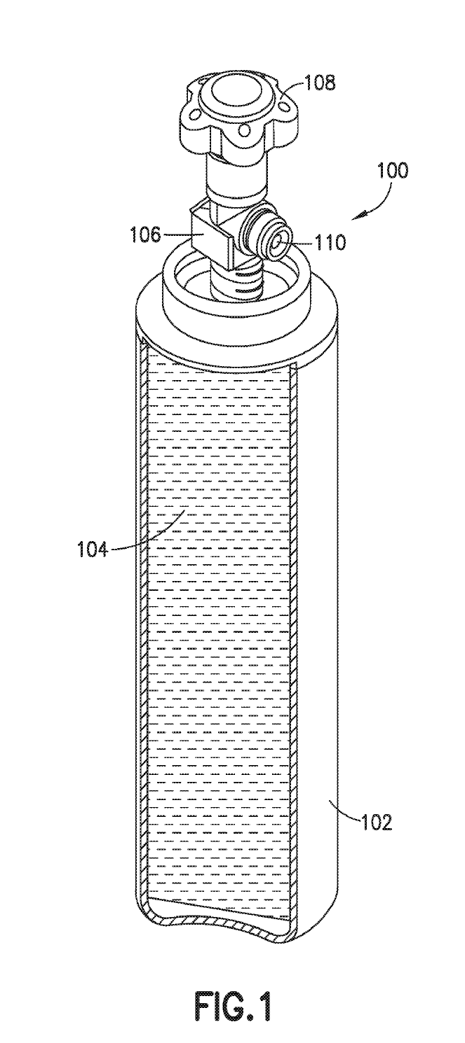

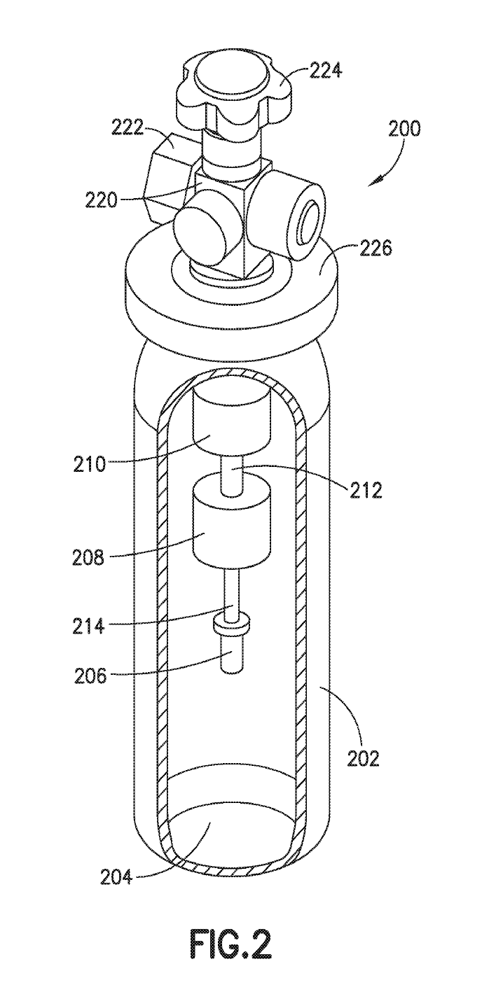

Gas supply vessels of such types are shown in FIGS. 1 and 2.

FIG. 1 is a perspective view, in partial section, of an adsorbent-based gas supply vessel 100 that may be utilized in a gas cabinet in accordance with the present disclosure. The vessel 100 includes a container 102 in which is disposed adsorbent 104. At its upper end, the container 102 is coupled to a valve head 106 including an interior valve chamber in which is disposed a valve element selectively translatable between fully open and fully closed positions. The valve chamber communicates with the interior volume of the container 102, as well as with a gas dispensing port 110. The valve element in the valve chamber is coupled with a valve actuator 108, which may comprise a hand wheel as shown, or alternatively an automatic actuator, such as a pneumatic actuator, electrical solenoid actuator, or other suitable automatic actuator.

The adsorbent 104 in the container 102 may be of any suitable type, and may for example comprise carbon adsorbent, aluminosilicate, silica, adsorbent clays, molecular sieves, or any other adsorbent that is suitable for use as a gas storage and dispensing medium, for adsorptive storage of gas during storage and transport conditions, and effective to desorptively release the gas for discharge from the container through the gas dispensing port 110 under dispensing conditions, with the valve element in the valve head 106 being opened for such dispensing.

Desorption of the gas from the adsorbent under dispensing conditions may be thermally-mediated desorption, in which the container and contained adsorbent are heated. Alternatively, desorption may be effected by pressure differential, e.g., with the gas dispensing port 110 being coupled to flow circuitry in which pressure is lower than pressure in the container 102. As a still further alternative, desorption may be affected by flowing through the interior volume of the container a carrier gas, to generate a mass transfer gradient resulting in release of adsorbed gas from the adsorbent and passage into the carrier gas for discharge from the vessel via the gas dispensing port 110. The foregoing modes of desorption and gas dispensing may be utilized in specific combinations in a given application, as appropriate to the gas involved and the end use thereof.

FIG. 2 is a perspective view, in partial section, of a pressure-regulated gas supply vessel 200 that may be utilized in a gas cabinet in accordance with the present disclosure. The vessel 200 includes a container 202 defining an enclosed interior volume 204. The container 202 at its upper end is coupled with a flange 226, which in turn is coupled with the valve head 220, containing a valve element in a valve chamber communicating with the interior volume 204 of the container 202 and with the gas discharge port 222 of the vessel. The valve element is coupled with actuator 224, which may comprise a manual hand wheel, as shown, or alternatively an automatic actuator of any suitable type.

The vessel 200 in container 202 holds an interior pressure-regulating assembly including a series-connected arrangement of pressure regulators 208 and 210 interconnected by gas dispensing conduit 212. Pressure regulator 208 in turn is connected by gas inlet tube 214 to a filter 206. The filter 206 may comprise a centered matrix or other filter element, for the purpose of preventing particulates from entering the gas discharge path including tube 214, pressure regulator 208, gas dispensing conduit 212, pressure regulator 210, and a gas dispensing conduit connecting the pressure regulator 210 with the valve head 220 (such gas dispensing conduit not visible in the view of FIG. 2).

The regulators 208 and 210 may be of a set point regulator type, in which the lower pressure regulator 208 has a higher set point pressure, and in which the upper pressure regulator 210 has a lower set point pressure, where in the respective set point pressures are provided to ensure dispensing of gas from the vessel in gas dispensing port 222 at a desired pressure condition.

The respective co-flow gases may be supplied by containers of the types shown in FIGS. 1 and 2, with the containers disposed in gas cabinets in which the containers are coupled with flow circuitry to supply the respective gases for the downstream gas-utilizing tool. The co-flow gases may be flowed in separate gas flow passages to the downstream tool, or alternatively, such gases may be mixed with one another, e.g., in a mixing chamber disposed in the gas cabinet.

By the provision of separate adsorbent-based or interiorly pressure-regulated vessels for the respective gases, the respective gases can be supplied at the low, e.g., subatmospheric, pressures, and such pressures may be the same as, or different from, one another. In this manner, by supply of different gases at different pressures, the blending of respective gases can be facilitated to pressure equalize, but with the unequal pressures in the first instance being used to effect the mixing of the gases and a highly efficient manner and at a desired relative proportion of each of the gas components to the other(s). For example, a lower flow rate, higher pressure gas may be mixed with a higher flow rate, lower pressure gas. Other variations of flow rates and pressures of specific gases in relation to the other(s) may be employed to provide a mixed gas composition in the downstream gas-utilizing tool.

Such mixing of co-flow gases may be effected by a gas mixing system in accordance with a further aspect of the present disclosure.

In many gas-utilizing process systems, specialty gas mixtures are employed, such as the above-described co-flow gas mixtures. In various processes, substantial benefit can be derived from the capability of changing the mix proportions of respective gas components of the mixture. This is particularly true in plasma doping processes utilized in process nodes of 32 nm and lower.

The gas mixing system of the present disclosure comprises a mixing manifold having the capability of generating multiple output mixtures, with only a few input gases. The gas mixing system features an isolated manifold that has mix isolation between output channels, cycle purging of the manifold to ensure gas mixture content, process tool communication, computer control with the ability to interlock channels to prevent accidental gas mixture contamination, gas sampling with metrology to confirm mix percentage, and long distance remote communication.

Such gas mixing system may be employed in a gas cabinet holding adsorbent-based and/or interiorly pressure-regulated gas supply vessels, as illustratively described hereinabove. The gas mixing system may comprise multiple pre-mixed inputs or post-mixed outputs. In various embodiments, the gas mixing system comprises a mixing manifold with two inputs and one output, with process tool communication and remote control.

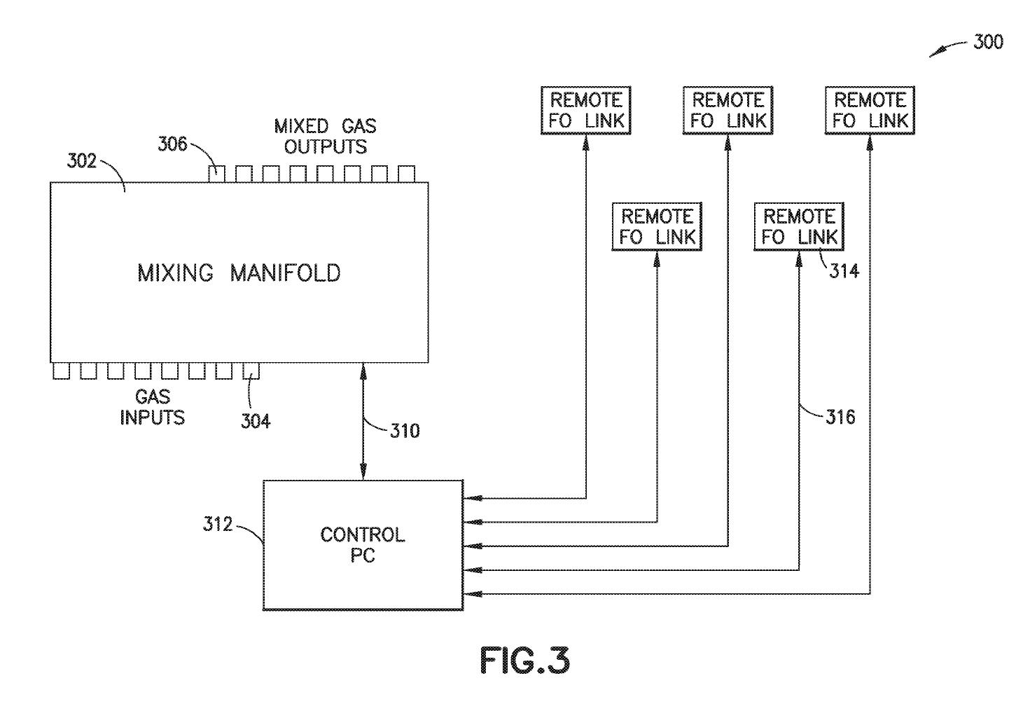

FIG. 3 is a schematic representation of a gas mixing system 300 according to a further embodiment of the disclosure, which may be utilized for supply of gas from gas supply vessels, e.g., in a gas cabinet of the present disclosure.

The gas mixing system 300 includes a gas mixing manifold 302 having multiple gas inputs 304 and multiple mixed gas outputs 306. The gas mixing manifold 302 is configured to be controlled by a central processor unit such as the Control PC 312 shown in FIG. 3 as being joined in bidirectional signal transmission relationship with the gas mixing manifold, by the bidirectional signal transmission line 310. Such signal transmission line accommodates transmission of control signals from the Control PC 312 to the mixing manifold 302, as well as monitoring and feedback signal transmission from the mixing manifold to the Control PC. To accommodate such monitoring and feedback signal transmission, the mixing manifold 302 may comprise appropriate monitoring, detection, and signal generation components, e.g., to monitor gas compositions, flow rates, pressures, temperatures, compositions, etc.

The Control PC 312 may be programmably configured to control the mixing manifold 302 in accordance with a predetermined cycle time program, e.g., involving actuation of actuators to close or open gas flow control valves associated with the gas inputs 304 and/or mixed gas outputs 306. More generally, the Control PC 312 may be programmably configured to control the operation of mixing manifold 302 in any suitable manner providing mixed gas to downstream gas-utilizing tool(s).

The gas mixing system 300 may also comprise interfaces enabled by fiber optics for long-distance interface connection with the local gas mixing system components, and the system may comprise multiple remote interfaces and associated communications capability so that it is arranged to supply mixed gas to multiple process tools by corresponding process tool connections. The local gas mixing manifold 302 may be installed in a gas cabinet of suitable type, as for example a TX 4 cabinet, commercially available from Entegris, Inc. (Billerica, Mass., USA), as configured for installation therein of adsorbent-based vessels such as the vessels commercially available from Entegris, Inc. (Billerica, Mass., USA) under the trademark SDS, and/or interiorly pressure-regulated vessels such as the vessels commercially available from Entegris, Inc. (Billerica, Mass., USA) under the trademark VAC.

As illustrated in FIG. 3, the gas mixing manifold 302 is controlled by the Control PC central processor unit 312 and input/output (I/O) drive, and may be provided with multiple (at least 2) input and output ports. The gas mixing system 300 may be provided as a standalone system, as an alternative to installation of the system or components thereof such as the mixing manifold 302, in a gas cabinet. The Control PC central processor unit 312 is shown as being linked by bidirectional fiber-optic transmission lines 316 to remote fiber-optic (FO) links 314.

In such arrangement, the mixing operation in the mixing manifold 302 can be effected by pre-programmed control from the Control PC 312 or remote interfaces associated with the remote fiber-optic links 314. The Control PC 312 and/or remote interfaces can also interface with the process tool or tools, and use control signals from the tool(s) to deliver a changed mixture of gas to the tool(s). In such manner, remote interfaces can be fiber-optically linked to allow very long distance signal transmission. Software interlocks may be employed for mixing operations to prevent incorrectly proportioned mixtures from being generated, or to avoid conflicts between process tool demands.

The mixing manifold therefore may be installed in or associated with a gas cabinet holding multiple gas supply vessels (of same or different sizes, types, etc.) for input of gases to the mixing manifold. The mixing manifold can be evacuated after each mixing operation, and the mixing manifold may comprise onboard sensors configured to detect and/or verify gas purity and gas component proportions in a gas mixture produced by the manifold.

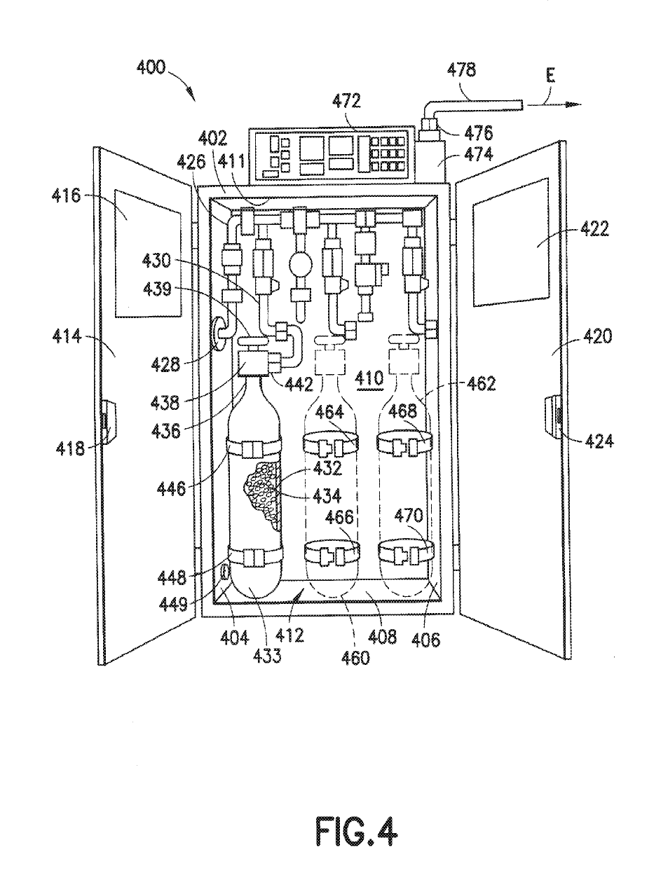

FIG. 4 is a front perspective view of a gas cabinet assembly incorporating adsorbent-based gas supply vessels according to one embodiment of the disclosure, with which the gas mixing system of FIG. 3 may be employed, e.g., with the mixing manifold 302 installed in the gas cabinet with associated flow circuitry coupled to the gas inputs 304 and mixed gas outputs 306 thereof. In lieu of adsorbent-based gas supply vessels alone, the gas cabinet assembly alternatively may incorporate interiorly pressure-regulated vessels, or as a still further alternative, a combination of adsorbent-based gas supply vessel(s) and interiorly pressure-regulated vessel(s).

The gas cabinet assembly 400 includes a gas cabinet 402. The gas cabinet 402 has side walls 404 and 406, floor 408, rear wall 410 and ceiling 411 that together define a housing with front doors 414 and 420. The housing and respective doors enclose an interior volume 412.

The doors may be arranged to be self-closing and self-latching in character. For such purpose, the door 414 may have a latch element 418 that cooperatively engages lock element 424 on door 420. The doors 414 and 420 may be beveled and/or gasketed in such manner as to produce a gas-tight seal upon closure of the doors.

The doors 414 and 420 as shown may be equipped with windows 416 and 422, respectively. The windows may by wire-reinforced and/or tempered glass, so as to be resistant to breakage, while at the same time being of sufficient area to afford an unobstructed view of the interior volume 412 and manifold 426, which may be of the simplified form shown in FIG. 4, or which may comprise a gas mixing manifold of a type as illustratively shown in FIG. 3.

The manifold 426 as shown may be arranged with an inlet connection line 430 that is joinable in closed flow communication with gas supply vessel 433. The manifold 426 may comprise any suitable components, including for example flow control valves, mass flow controllers, process gas monitoring instrumentation for monitoring the process conditions of the gas being dispensed from the supply vessel, such as pressure, temperature, flow rate, concentration, and the like, manifold controls, including automated switching assemblies for switchover of the gas supply vessels when a multiplicity of such vessels is installed in the gas cabinet, leak detection devices, automated purge equipment and associated actuators for purging the interior volume of the gas cabinet when a leak is detected from one or more of the supply vessels.

The manifold 426 connects to an outlet 428 at the wall 404 of the cabinet, and the outlet 428 may in turn be connected to piping for conveying the gas dispensed from the supply vessel to a downstream gas-utilizing unit coupled with the gas cabinet.

The gas-utilizing unit may for example comprise an ion implanter, chemical vapor deposition reactor, photolithography track, diffusion chamber, plasma generator, oxidation chamber, etc. The manifold 426 may be constructed and arranged for providing a predetermined flow rate of the dispensed gas from the supply vessel and gas cabinet to the gas-utilizing unit.

The gas cabinet has a roof-mounted display 472 coupled with the manifold elements and ancillary elements in the interior volume of the cabinet, for monitoring the process of dispensing the gas from the gas supply vessel(s) in the interior volume of the cabinet.

The gas cabinet may also be provided with a roof-mounted exhaust fan 474 that is coupled by coupling fitting 476 to discharge conduit 478 for discharge of gas from the interior volume of the cabinet, in the direction indicated by arrow E. The exhaust fan 474 may be operated at appropriate rotational speed to impose a predetermined vacuum or negative pressure in the interior volume of the cabinet, as a further protective measure against any undesirable efflux of gas leakage from the gas cabinet. The discharge conduit may therefore be coupled to a downstream gas treatment unit (not shown), such as a scrubber or extraction unit for removing any leakage gas from the exhaust stream. In order to provide a supply of inflowing air for such purpose, the cabinet, e.g., the doors, may be constructed to allow a net inflow of ambient air as a sweep or purge stream for clearing the interior volume gas from the cabinet. Thus, the doors may be louvered, or otherwise be constructed for ingress of ambient gas.

The gas supply vessel 433 may suitably comprise a leak-tight gas container, including a wall 432 enclosing an interior volume of the vessel. Disposed in the interior volume of the container is a particulate solid sorbent medium, e.g., a physical adsorbent material such as carbon, molecular sieve, silica, alumina, etc. The sorbent may be of a type that has a high sorptive affinity and capacity for the gas to be dispensed.

For applications such as semiconductor manufacturing, in which dispensed reagent gases are preferably of ultra-high purity, e.g., “7-9's” purity, more preferably “9-9's” purity, and even higher, the sorbent material must be substantially free, and preferably essentially completely free, of any contaminant species that would cause decomposition of the stored gas in the vessel and cause the vessel interior pressure to rise to levels significantly above the desired set point storage pressure.

For example, it may be desirable to utilize the sorbent-based storage and dispensing vessel of the invention to retain gas in the stored state at pressure not significantly exceeding atmospheric pressure, e.g., in a range of from about 25 to about 800 torr. Such atmospheric or below atmospheric pressure levels provide a level of safety and reliability in relation to the use of high pressure compressed gas cylinders.

As shown in FIG. 4, the gas supply vessel 433 is of elongate vertically upstanding form, having a lower end that is reposed on the floor 408 of the cabinet, and with an upper neck portion 436 to which is secured a valve head 438 to leak-tightly seal the vessel. In its fabrication, the gas supply vessel 433 may be filled with adsorbent and thereafter, before or after the sorbate gas is loaded on the sorbent, the valve head 438 may be secured to the vessel neck portion, e.g., by welding, brazing, soldering, compressive joint fixturing with a suitable sealant material, etc., so that the vessel thereafter is leak-tight in character at the neck joint with the valve head.

The valve head 438 is provided with a coupling 442 for joining the gas supply vessel to suitable piping or other flow means permitting selective dispensing of gas from the vessel. The valve head may be provided with a hand wheel 439 for manually opening or closing the valve in the valve head, to flow or terminate the flow of gas into the connecting piping. Alternatively, the valve head may be provided with an automatic valve actuator that is linked to suitable flow control means, whereby the flow of gas during the dispensing operation is maintained at a desired level.

In operation, a pressure differential between the interior volume of the gas supply vessel 433 and the exterior piping/flow circuitry of the manifold is established to cause gas to desorb from the sorbent material and to flow from the vessel into the gas flow manifold 426. A concentration driving force for mass transfer is thereby created, by which gas desorbs from the sorbent and passes into the free gas volume of the vessel, to flow out of the vessel while the valve in the valve head is open.

Alternatively, the gas to be dispensed may be at least partially thermally desorbed from the sorbent in the gas supply vessel 433. For such purpose, the floor 408 of the gas cabinet may have an electrically actuatable resistance heating region on which the vessel is reposed, so that electrical actuation of the resistance heating region of the floor causes heat to be transferred to the vessel and the sorbent material therein. As a result of such heating, the stored gas desorbs from the sorbent in the vessel and may be subsequently dispensed.

The gas supply vessel may alternatively be heated for such purpose by deployment of a heating jacket or a heating blanket that enwraps or surrounds the vessel casing, so that the vessel and its contents are appropriately heated to effect the desorption of the stored gas, and subsequent dispensing thereof.

As a further approach, the desorption of the stored gas in the gas supply vessel may be carried out under the impetus of both pressure-differential-mediated desorption and thermally-mediated desorption.

As yet another alternative, the supply vessel may be provided with a carrier gas inlet port 449, which may be connected to a source of carrier gas (not shown) either interior or exterior to the cabinet. Such gas source may provide a flow of suitable gas, e.g., an inert gas or other gas that is non-deleterious to the process in the downstream gas-utilizing unit. In such manner, gas may be flowed through the vessel to cause a concentration gradient to be developed that will effect desorption of the adsorbate gas from the adsorbent in the vessel. The carrier gas may be a gas such as nitrogen, argon, krypton, xenon, helium, etc.

As shown in FIG. 4, the gas supply vessel 433 is held in place in the gas cabinet by strap fasteners 446 and 448 of a conventional type. Other fasteners could be used, such as neck rings, or other securement structures may be employed, such as receiving depressions or cavities in the floor of the gas cabinet, that matably receive the lower end of the vessel therein, guide members or compartment structures that fixedly retain the vessel in a desired position in the interior volume of the gas cabinet.

Although only one gas supply vessel 433 is shown in the gas cabinet in FIG. 4, such gas cabinet is shown as being constructed and arranged to retain one, two or three vessels therein. In addition to the gas supply vessel 433, an optional second gas supply vessel 460 and an optional third gas supply vessel 462 are shown in dashed line representation in FIG. 4, being associated with the respective strap fasteners 464 and 466 (for optional gas supply vessel 460) and strap fasteners 468 and 470 (for optional gas supply vessel 462).

It will be apparent that the gas cabinet of the disclosure may be widely varied, to contain one or more than one gas supply vessel therein. In such manner, any number of gas supply vessels can be retained in a single unitary enclosure, thereby providing enhanced safety and process reliability in the management of the supplied gas.

In such manner, a multiplicity of adsorbent-containing gas supply vessels and/or interiorly pressure-regulated vessels and/or vessels of any other appropriate type may be provided, for sourcing of the various gas components needed in the downstream gas-consumption unit, or to provide multiple vessels each containing the same gas. The gases in multiple vessels in the gas cabinet may thus be the same as or different from one another, and the respective vessels may be concurrently operated to extract gas therefrom for the downstream gas-consumption unit, or the respective vessels may be operated by a cycle timer program and automated valve/manifold operation means, to successively open the vessels in turn to provide continuity of operation, or otherwise to accommodate the process requirements of the downstream gas-consumption unit.

The display 472 may be programmatically arranged with associated computer/microprocessor means to provide visual output indicative of the status of process operation, the volume of the dispensed gas flowed downstream, the remaining time or gas volume for the dispensing operation, etc. The display may be arranged to provide output indicating the time or frequency of maintenance events for the gas cabinet, or any other suitable information appropriate to the operation, use and maintenance of the gas cabinet assembly, such as the operation of a mixing manifold of the type shown in FIG. 3 when installed in the gas cabinet.

The display may also comprise audible alarm output means, signalling the need for change-out of the vessels in the gas cabinet, a leakage event, approach of cycle termination, or any event, state or process condition that is useful in the operation, use and maintenance of the gas cabinet.

It will therefore be appreciated that the gas cabinet assembly may be widely varied in form and function, to provide a flexible means for sourcing reagent gas(es) to a downstream gas-utilizing unit, such a process unit in a semiconductor manufacturing facility. The supplied gas from the gas cabinet assembly may be of any suitable type, and may for example comprise any one or more of hydride gases, halide gases, and gaseous organometallic Group V compounds, including, for example, silane, diborane, germane, ammonia, phosphine, arsine, stibine, hydrogen sulfide, hydrogen selenide, hydrogen telluride, boron trifluoride, tungsten hexafluoride, chlorine, hydrogen chloride, hydrogen bromide, hydrogen iodide, hydrogen fluoride, germanium tetrafluoride, etc., and such gases may include co-flow gas species in mixture therewith, such as hydrogen, xenon, argon, ammonia, carbon monoxide, carbon dioxide, etc.

The gas cabinet assembly may have a mixing manifold of the type shown in FIG. 3 installed therein, together with gas supply vessels of the type described hereinabove in connection with FIGS. 1 and 2, to provide gas of appropriate composition and characteristics to one or more process tools in a flexible, cost-effective, and efficient manner.

While the disclosure has been set forth herein in reference to specific aspects, features and illustrative embodiments, it will be appreciated that the utility of the disclosure is not thus limited, but rather extends to and encompasses numerous other variations, modifications and alternative embodiments, as will suggest themselves to those of ordinary skill in the field of the present disclosure, based on the description herein. Correspondingly, the disclosure as hereinafter claimed is intended to be broadly construed and interpreted, as including all such variations, modifications and alternative embodiments, within its spirit and scope.

1. A gas supply system, comprising:
at least one gas supply vessel susceptible to cooling in dispensing operation involving diminution of pressure of gas dispensed from the vessel;
a monitoring system configured to detect diminution of pressure to pressure that is indicative of exhaustion of the vessel, and to terminate dispensing operation of the vessel; and
a warming system configured to warm the vessel upon termination of dispensing operation thereof so that the vessel is warmed to an extent so that pressure of remaining gas in the vessel is increased above the pressure indicative of exhaustion of the vessel, to thereby enable renewed dispensing operation of the vessel.

2. The gas supply system of claim 1, wherein the gas supply vessel contains an adsorbent as a storage medium for gas to be supplied by the vessel in dispensing operation comprising gas desorption from the adsorbent.

3. The gas supply system of claim 2, wherein the adsorbent comprises carbon adsorbent.

4. The gas supply system of claim 1, wherein the warming system comprises a heater arranged to heat the gas supply vessel.

5. The gas supply system of claim 1, wherein the warming system comprises a heating jacket arranged to heat the gas supply vessel.

6. The gas supply system of claim 1, comprising a multiplicity of the gas supply vessels, operatively arranged so that when the monitoring system terminates dispensing operation of a first vessel, a second vessel initiates dispensing operation, to ensure continuity of gas supply.

7. The gas supply system of claim 6, operatively arranged so that when the first vessel is warmed to enable its renewed dispensing operation, dispensing operation of the second vessel is terminated and renewed dispensing operation of the warmed first vessel is initiated.

8. The gas supply system of claim 1, wherein the at least one gas supply vessel is disposed in a gas cabinet.

9. The gas supply system of claim 8, comprising multiple gas supply vessels in the gas cabinet, operatively arranged with a mixing manifold for mixing gas dispensed from two or more of the multiple gas supply vessels.

10.-11. (canceled)

12. A gas mixing system, comprising:
a gas mixing manifold having multiple gas inputs have multiple mixed gas outputs;
a monitoring and control system configured to operate the gas mixing manifold and to receive feedback therefrom via signal transmission lines; and
at least one remote fiber-optic link interconnecting the monitoring and control system with at least one remote input/output interface unit.

13. The gas mixing system of claim 12, wherein the remote input/output interface unit is configured to transmit control signals either directly to the gas mixing manifold for operation thereof or to the monitoring and control system for operation of the gas mixing manifold.

14. The gas mixing system of claim 13, comprising multiple remote input/output interface units, wherein the gas mixing system is configured with software interlocks to prevent incorrectly proportioned mixtures from being generated, and/or to avoid conflicts between process tool demands of one or more process tools coupled in gas mixture receiving relationship to the gas mixing manifold.

15. The gas mixing system of claim 12, wherein the gas mixing manifold is disposed in a gas cabinet.

16. The gas mixing system of claim 12, as configured for evacuation of the mixing manifold after each mixing operation therein.

17. The gas mixing system of claim 12, wherein the mixing manifold comprises onboard sensors configured to detect and/or verify gas purity and/or gas component proportions in a gas mixture produced by the manifold.

18. A method of supplying gas from at least one gas supply vessel that is susceptible to cooling in dispensing operation involving diminution of pressure of gas dispensed from the vessel, said method comprising:
monitoring pressure of gas dispensed from the vessel;
upon detection of diminution of pressure to pressure that is indicative of exhaustion of the vessel, terminating dispensing operation of the vessel; and
warming the vessel upon termination of dispensing operation thereof so that the vessel is warmed to an extent so that pressure of remaining gas in the vessel is increased above the pressure indicative of exhaustion of the vessel, to thereby enable renewed dispensing operation of the vessel.

19. (canceled)

20. A method of supplying mixed gas, comprising mixing gases from different gas supply vessels in a gas mixing system according to claim 12, and discharging mixed gas from the gas mixing manifold in one of the multiple mixed gas outputs thereof.
